(19) United States
(12) Patent Application Publication
(10) Pub. No.: US 2022/0129710 A1
(43) Pub. Date: Apr. 28, 2022

(54) SYSTEM AND METHOD FOR CLASSIFYING ELEMENTS OF A PRODUCT

(71) Applicant: HCL TECHNOLOGIES LIMITED, New Delhi (IN)

(72) Inventors: Ravi Krishnan VENKATARAMAN, Navi Mumbai (IN); Pankaj GUPTA, Navi Mumbai (IN)

(73) Assignee: HCL TECHNOLOGIES LIMITED, New Delhi (IN)

(21) Appl. No.: 17/352,160

(22) Filed: Jun. 18, 2021

(30) Foreign Application Priority Data
Oct. 26, 2020 (IN) 202011046694

(51) Int. Cl. G06K 9/62; G06F 30/17

(52) U.S. Cl. CPC G06K 9/6268; G06K 9/6281; G06K 9/6202; G06F 30/17

(57) ABSTRACT

Disclosed is a method and system for classifying elements of a product. The method comprises identifying elements of the product. Thereupon, features of the one or more elements are determined, using a feature recognition technique. The features correspond to manufacturing operations required for manufacturing the elements, and include sheet metal operations, turn operations, injection moulding operations, and machining operations. The manufacturing operations are determined in a priority order with the sheet metal operation having a highest priority and the machining operation having a least priority.

### CROSS-REFERENCE TO RELATED APPLICATIONS AND PRIORITY

The present application claims benefit from Indian Patent Application No. 202011046694 filed on 26 Oct. 2020 the entirety of which is hereby incorporated by reference.

### TECHNICAL FIELD

The present subject matter described herein, in general, relates to mechanical automation, and more particularly to a system and a method for automatically identifying mechanical operations required to manufacture elements of a product.

### BACKGROUND

Automation is the order of the day in today's manufacturing world. There exists a large pool of assembly components without manufacturing information. An automated system and method for generating information about manufacturing requirements of a product is required. Such information could be used in process planning, cost planning, and plans related to development of mechanical products.

Existing modeler tools like SolidWorks, NX, CREO, and Catia can merely assist in designing assemblies but they lack the capability to determine mechanical operations required to develop a component present in a product. Thus, there remains a need to develop such system and method using which mechanical operations required to develop components present in a product could be identified, and subsequently such information could be used to manufacture the components.

### SUMMARY

Before the present systems and methods for classifying elements of a product are described, it is to be understood that this application is not limited to the particular systems, and methodologies described, as there can be multiple possible embodiments which are not expressly illustrated in the present disclosures. It is also to be understood that the terminology used in the description is for the purpose of describing the particular implementations or versions or embodiments only and is not intended to limit the scope of the present application.

This summary is provided to introduce aspects related to a system and a method for classifying elements of a product. This summary is not intended to identify essential features of the claimed subject matter nor is it intended for use in determining or limiting the scope of the claimed subject matter.

In one implementation, a system for classifying elements of a product is disclosed. In one aspect, the system comprises a memory and a processor coupled to the memory. Further, the processor may be capable of executing instructions in the memory to perform one or more steps. In the aspect, the system may identify one or more elements of the product. The system may further determine, using a feature recognition technique, features of the one or more elements. The features correspond to manufacturing operations required for manufacturing the one or more elements, and include sheet metal operations, turn operations, injection moulding operations, and machining operations. The manufacturing operations are determined in a priority order with the sheet metal operation having a highest priority and the machining operation having a least priority.

In one implementation, a method for classifying elements of a product is disclosed. In one aspect, the method may comprise identifying one or more elements of the product. The method may further comprise determining, using a feature recognition technique, features of the one or more elements. The features correspond to manufacturing operations required for manufacturing the one or more elements, and include sheet metal operations, turn operations, injection moulding operations, and machining operations. The manufacturing operations are determined in a priority order with the sheet metal operation having a highest priority and the machining operation having a least priority.

### BRIEF DESCRIPTION OF THE DRAWINGS

The foregoing detailed description of embodiments is better understood when read in conjunction with the appended drawings. For the purpose of illustrating of the present subject matter, an example of construction of the present subject matter is provided as figures; however, the invention is not limited to the specific method and system disclosed in the document and the figures.

The present subject matter is described in detail with reference to the accompanying figures. In the figures, the left-most digit(s) of a reference number identifies the figure in which the reference number first appears. The same numbers are used throughout the drawings to refer various features of the present subject matter.

FIG. 1 illustrates a network architecture diagram 100 of a system 102 and devices 104 connected together for classifying elements of a product, in accordance with an embodiment of the present subject matter.

FIG. 2 illustrates a block level diagram of the system 102, in accordance with an embodiment of the present subject matter.

FIG. 3a illustrates a wall, in accordance with an embodiment of the present subject matter.

FIG. 3b illustrates a bend, in accordance with an embodiment of the present subject matter.

FIG. 3c illustrates a flange, in accordance with an embodiment of the present subject matter.

FIG. 3d illustrates a stamp, in accordance with an embodiment of the present subject matter.

FIG. 4a illustrates an external end profile, in accordance with an embodiment of the present subject matter.

FIGS. 4b and 4c illustrate internal end profile, in accordance with an embodiment of the present subject matter.

FIGS. 5a and 5b illustrate a rib, in accordance with an embodiment of the present subject matter.

FIGS. 5c and 5d illustrate a rib, in accordance with an embodiment of the present subject matter.

FIG. 5e illustrates a boss, in accordance with an embodiment of the present subject matter.

FIG. 6a illustrates a blind pocket, and FIG. 6b illustrates a through pocket, in accordance with an embodiment of the present subject matter.

FIG. 6c illustrates a blind slot, and FIG. 6d illustrates islands, in accordance with an embodiment of the present subject matter.

FIG. 7 illustrates an exemplary product, in accordance with an embodiment of the present subject matter.

FIG. 7a illustrates a 3D representation of a Bush, and FIG. 7a′ illustrates a 2D representation of the Bush, in accordance with an embodiment of the present subject matter.

FIG. 7b illustrates a 3D representation of a Pivot, and FIG. 7b′ illustrates a 2D representation of the Pivot, in accordance with an embodiment of the present subject matter.

FIG. 7c illustrates a 3D representation of a U-Support, and FIG. 7c′ illustrates a 2D representation of the U-Support, in accordance with an embodiment of the present subject matter.

FIG. 7d illustrates a 3D representation of a Pin, and FIG. 7d′ illustrates a 2D representation of the Pin, in accordance with an embodiment of the present subject matter.

FIG. 7e illustrates a 3D representation of a Bracket, and FIG. 7e′ illustrates a 2D representation of the Bracket, in accordance with an embodiment of the present subject matter.

FIG. 8 illustrates a method 800 for classifying elements of a product, in accordance with an embodiment of the present subject matter.

### DETAILED DESCRIPTION

Some embodiments of this disclosure, illustrating all its features, will now be discussed in detail. The words “comprising,” “having,” “containing,” and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise.

Although any systems and methods for classifying elements of a product, similar or equivalent to those described herein can be used in the practice or testing of embodiments of the present disclosure, the exemplary, systems and methods for classifying elements of a product are now described. The disclosed embodiments for classifying elements of a product are merely examples of the disclosure, which may be embodied in various forms.

Various modifications to the embodiment will be readily apparent to those skilled in the art and the generic principles herein may be applied to other embodiments for classifying elements of a product. However, one of ordinary skill in the art will readily recognize that the present disclosure for classifying elements of a product is not intended to be limited to the embodiments described, but is to be accorded the widest scope consistent with the principles and features described herein.

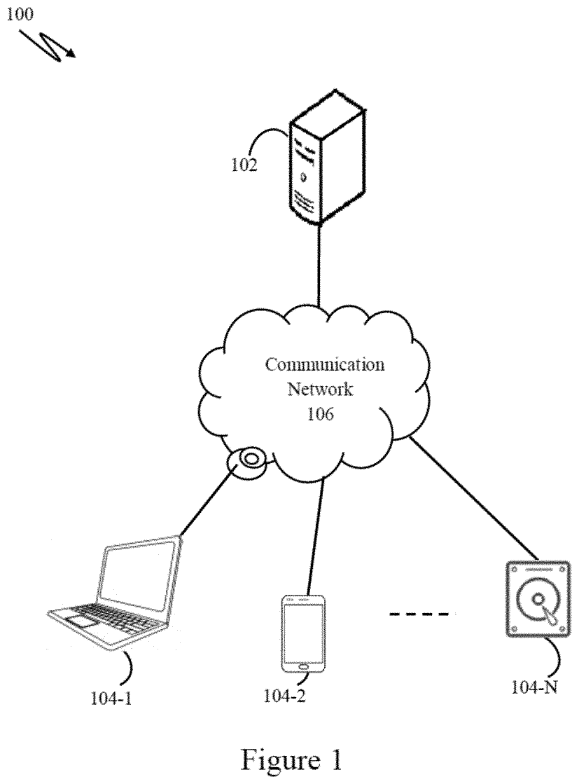

Referring now to FIG. 1, a network implementation diagram 100 of a system 102 for classifying elements of a product, in accordance with an embodiment of the present subject matter may be described. In one example, the system 102 may be connected with devices 104-1 through 104-N (collectively referred as 104) through a communication network 106.

It should be understood that the system 102 and the devices 104 are different computing devices. The system 102 may be implemented in a variety of computing systems, such as a laptop computer, a desktop computer, a notebook, a workstation, a mainframe computer, a server, a network server, a cloud-based computing environment, and a mobile. The devices 104 may include a laptop 104-1, a smart phone 104-2, or a data storage device such as a Hard Disk Drive (HDD) 104-N. The devices 104 may be used for providing a 3-Dimensional (3D) model of the product. Upon receiving the 3D model from the devices 104, the system 102 may perform further processing, as described in later sections.

In one implementation, the communication network 106 may be a wireless network, a wired network, or a combination thereof. The communication network 106 can be implemented as one of the different types of networks, such as intranet, Local Area Network (LAN), Wireless Personal Area Network (WPAN), Wireless Local Area Network (WLAN), wide area network (WAN), the internet, and the like. The communication network 106 may be either a dedicated network or a shared network. The shared network represents an association of the different types of networks that use a variety of protocols, for example, MQ Telemetry Transport (MQTT), Extensible Messaging and Presence Protocol (XMPP), Hypertext Transfer Protocol (HTTP), Transmission Control Protocol/Internet Protocol (TCP/IP), Wireless Application Protocol (WAP), and the like, to communicate with one another. Further, the communication network 106 may include a variety of network devices, including routers, bridges, servers, computing devices, storage devices, and the like.

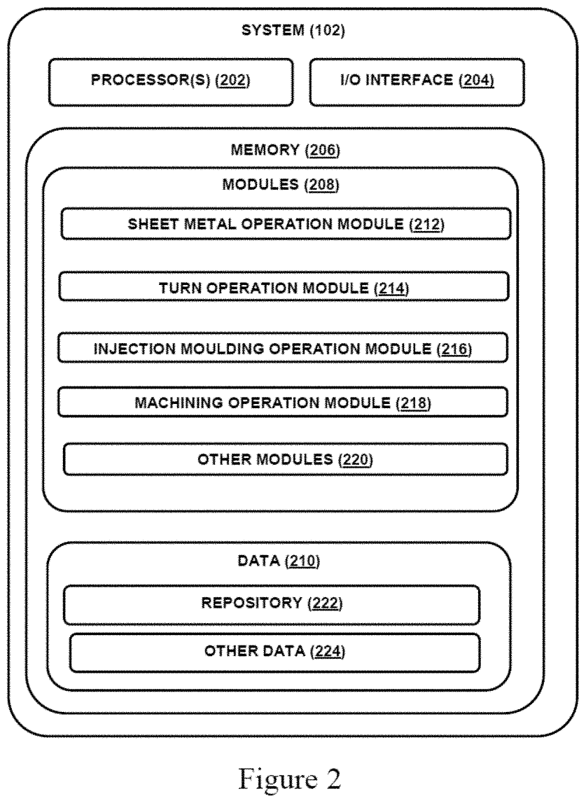

Referring now to FIG. 2, a block diagram 200 of the system 102 is illustrated in accordance with an embodiment of the present subject matter. In one embodiment, the system 102 may include at least one processor 202, an input/output (I/O) interface 204, and a memory 206. The at least one processor 202 may be implemented as one or more microprocessors, microcomputers, microcontrollers, digital signal processors, central processing units, state machines, logic circuitries, and/or any devices that manipulate signals based on operational instructions. Among other capabilities, the at least one processor 202 may be configured to fetch and execute computer-readable instructions stored in the memory 206.

The I/O interface 204 may include a variety of software and hardware interfaces, for example, a web interface, a graphical user interface, a command line interface, and the like. The I/O interface 204 may allow a user to interact with the system 102. Further, the I/O interface 204 may enable the system 102 to communicate with the user devices 104, and other computing devices, such as web servers and external data servers (not shown). The I/O interface 204 can facilitate multiple communications within a wide variety of networks and protocol types, including wired networks, for example, LAN, cable, etc., and wireless networks, such as WLAN, cellular, or satellite. The I/O interface 204 may include one or more ports for connecting a number of devices to one another or to another server.

The memory 206, amongst other things, serves as a repository for storing data processed, received, and generated by one or more of modules 208. The memory 206 may include any computer-readable medium or computer program product known in the art including, for example, volatile memory, such as Static Random Access Memory (SRAM) and Dynamic Random Access Memory (DRAM), and/or non-volatile memory, such as Read Only Memory (ROM), Erasable Programmable ROM (EPROM), Electrically Erasable and Programmable ROM (EEPROM), flash memories, hard disks, optical disks, and magnetic tapes.

The memory 206 may include data generated as a result of the execution of one or more of the modules 208. In one implementation, the memory 206 may include data 210. The modules 208 include routines, programs, objects, components, data structures, etc., which perform particular tasks or implement particular abstract data types. In one implementation, the modules 208 may include a sheet metal operation module 212, a turn operation module 214, an injection moulding operation module 216, a machining operation module 218, and other modules 220. The other modules 220 may include programs or coded instructions that supplement applications and functions of the system 102. The modules 208 described herein may be implemented as software modules that may be executed in the cloud-based computing environment of the system 102.

The data 210 may include a repository 222 for storing data processed, computed, received, and generated by one or more of the modules 208. Furthermore, the data 210 may include other data 224 for storing data generated as a result of the execution of one or more modules in the other modules 220.

In one implementation, at first, a 3-Dimensional (3D) representation of the product is obtained. Alternatively, a 3D model of the product may be inputted to the system. The 3D model of the product may be used to capture details of the product from an appropriate view, such as a top view, a bottom view, a front view, a back view, a side view, or a perspective view.

Successively, features of the one or more elements of the product may be determined using a feature recognition technique. The feature recognition technique operates on boundary representation models of products. The features may correspond to manufacturing operations required for manufacturing the one or more elements. Such manufacturing operations may include sheet metal operations, turn operations, injection moulding operations, and machining operations. In one preferred embodiment, the manufacturing operations are determined in a priority order with the sheet metal operation having a highest priority and the machining operation having a least priority, amongst the listed four operations.

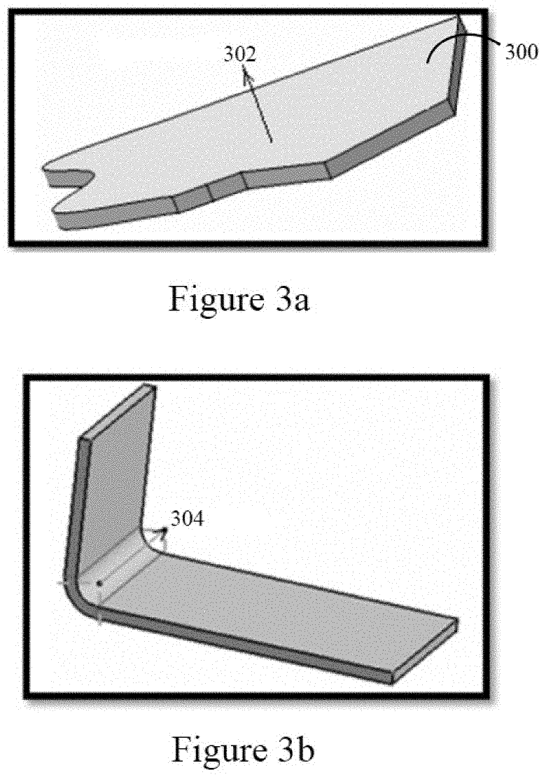

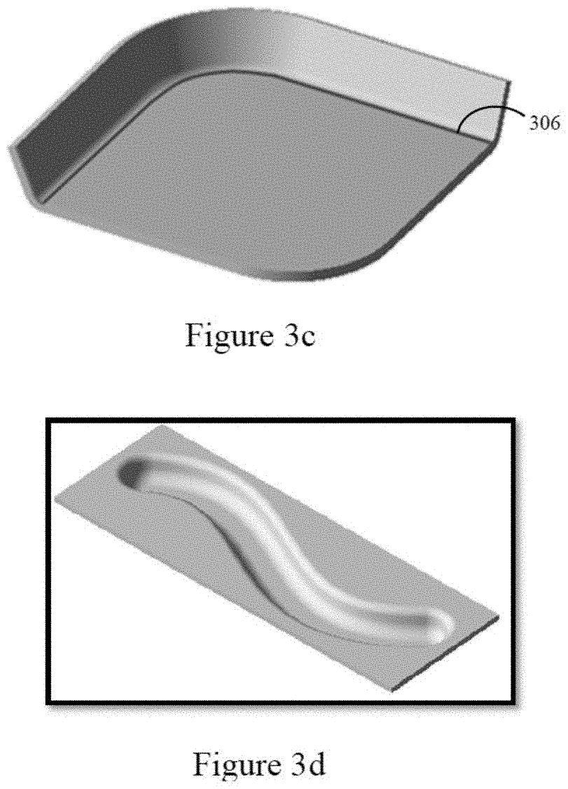

In one embodiment, features such as walls, bends, cut-outs, flanges, and stamps may be identified by the sheet metal operation module 212, to be manufactured using the sheet metal operations. Main criterion for recognition of features related to the sheet metal operations is that an element should have a uniform thickness. A wall, as illustrated in FIG. 3a, is characterized by two parallel planar faces offset by thickness. FIG. 3a also shows a top surface 300 and a wall direction 302. The top surface and a bottom surface of the wall can be of any shape. A bend, as illustrated in FIG. 3b, is defined as a thin sheet having uniform thickness and having both top and bottom faces of either cylindrical or conical shapes. FIG. 3b also shows a bend axis 304. A flange, as illustrated in FIG. 3c, is defined by a profile, swept along a path. The profile as well path of the flange can be multi-segment. FIG. 3c also shows a path edge 306 of the flange. A stamp, as illustrated in FIG. 3d, is a feature created by embossing sheets.

In one embodiment, features such as an external end profile feature and an internal end profile feature may be identified to be manufactured using the turn operations, by the turn operation module 214. The turn module recognizes axis-symmetric features mainly found on elements. Input provided to the turn module is a potential axis about which the element is going to be manufactured. A foremost criterion for the turn operations is that the element should consist of cylindrical and conical faces. Once this criterion is satisfied, the turn operation module 214 can operate on the product for recognising potential turn features. Presence of turn features ensures the element to be manufactured using lathe operations.

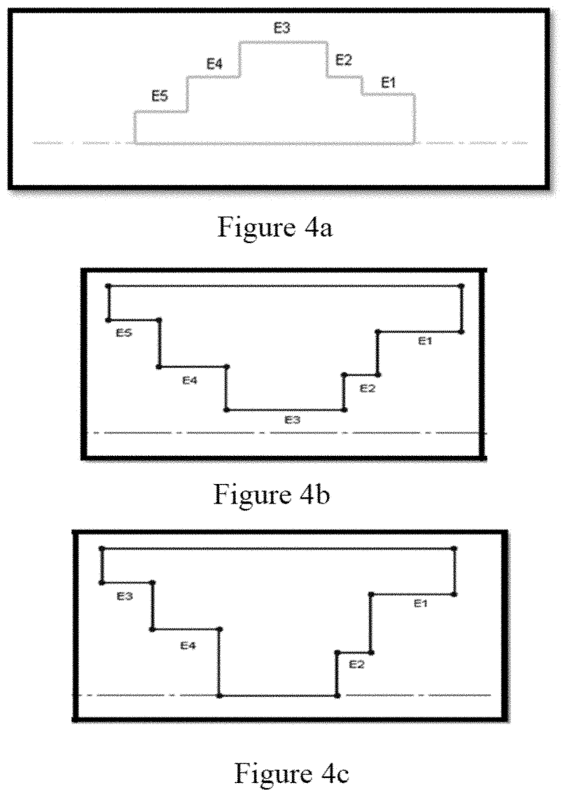

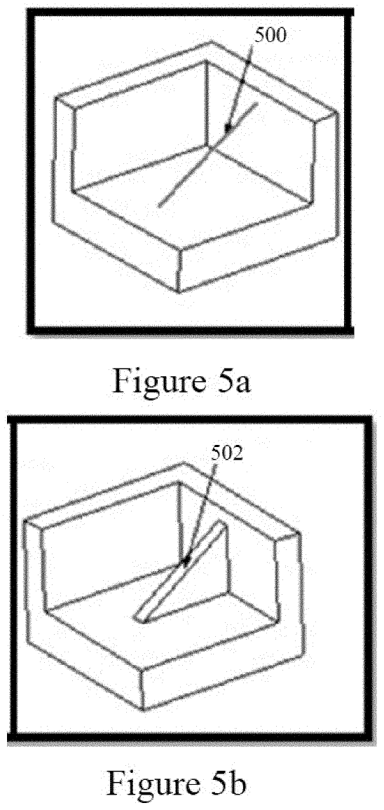

The turn operation module 214 may operate using a turn feature. The turn feature may include details for recognizing an external end profile feature. The external end profile feature, as illustrated in FIG. 4a, is a composition of consecutive external element features with monotonically increasing or equal diameters. The external end profile feature always starts from one side of the part and stops at one of the neighbour external element features with largest diameter. The external end profile feature is usually machined with a face down process or outer turning operation towards chuck. The external end profile feature only exists at either side of a element, so a maximum of two external end profile features can be formed. As visible in FIG. 4a, two external end profile features share one common external element feature E3. Therefore, E1, E2, and E3 form one external end profile feature on one direction and E5, E4, and E3 form another external end profile feature on another direction.

The turn feature library may also include details for recognizing an internal end profile feature. To an extent, the internal end profile feature is similar to the external end profile feature, but constituent features are internal. Thus, the internal end profile feature is a composition of consecutive internal element features with monotonically equal or decreasing diameters, as illustrated in FIGS. 4b and 4c. The internal end profile feature always starts from one side of an element and stops at one neighbour component features with smallest diameter. The internal end profile feature is usually machined with a face up process or an inner turning operation towards the chuck. As visible in FIG. 4b, internal element feature E3 is shared by two internal end profile features. Further, as visible in FIG. 4c, sharing of an internal element feature is not possible.

Features such as ribs and boss may be identified to be manufactured using the injection moulding operations by the injection moulding operation module 216. The injection moulding operation module 216 may operate based on an injection moulding feature including details for recognizing the ribs and boss features. Presence of the ribs and rib networks indicates that the element is going to be manufactured using the injection moulding process. Further, presence of the boss features is an additional criterion for classifying the elements for Injection moulding process.

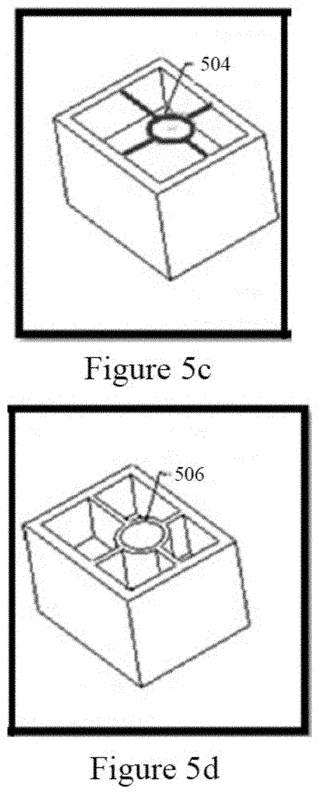

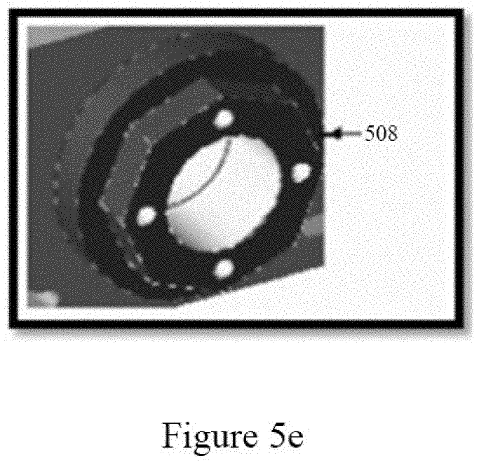

A profile of a rib 500 can be present as shown in FIG. 5a. A rib feature 502 can have two or more parallel faces separated by a small distance, as illustrated in FIG. 5b. Such distance corresponds to a thickness of the rib. Typically, the thickness ranges from 3-5 mm for most of the parts. Parallelism restriction is waived for drafted ribs. Rib networks are formed as a collection of ribs. A rib network profile 504 can be present as shown in FIG. 5c. Further, FIG. 5d illustrates an exemplary rib network 506. The rib network 506 is created by making a planar profile and extruding the profile in a direction perpendicular to profile plane. A thickness is also given to the profile during an extrude operation. In normal ribs, the profile is thickened along a normal of the profile plane; while in a rib network, the profile is thickened perpendicular to the profile plane. A boss 508, as illustrated in FIG. 5e, is a stand-alone protruding feature present on a base.

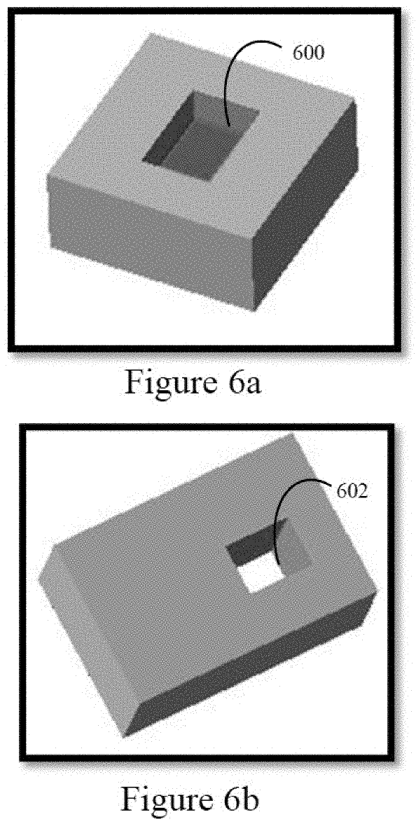

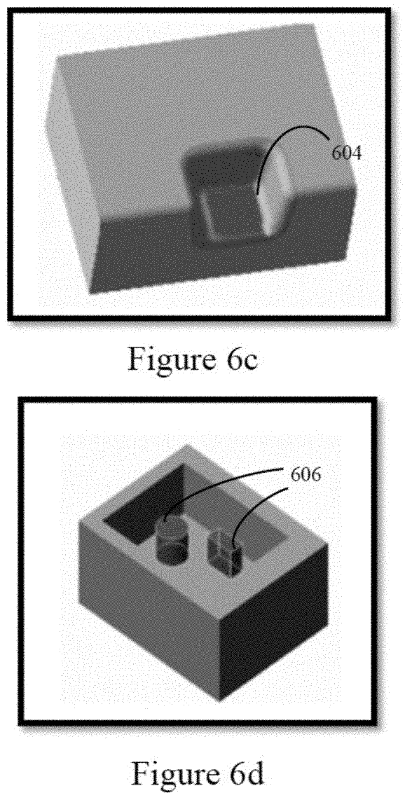

In one embodiment, features such as holes, pockets, slots, and islands may be identified to be manufactured using the machining operations by the machining operation module 218. The machining operations may be performed by a Computerised Numeric Control (CNC) machine. The machining operation module 218 may operate based on a machining library including details to recognize holes of different types, such as counter-bore holes, counter-sunk holes, counter-drill holes, taper holes, and simple holes. Holes are depressions in elements with cylindrical, conical, or toroidal side faces. The machining library may also include details to recognize pockets. The pockets are feature that are completely covered from all sides. The pockets are either blind pockets or through pockets. A blind pocket 600, as illustrated in FIG. 6a, have defined bottom. A through pocket 602, as illustrated in FIG. 6b, does not have a defined bottom. A slot is a pocket feature having multiple openings. The slots are either blind slots or through slots. A blind slot 604 is illustrated in FIG. 6c, as an example. Islands 606 are identified as protrusion features present on pockets or slots, as illustrated in FIG. 6d.

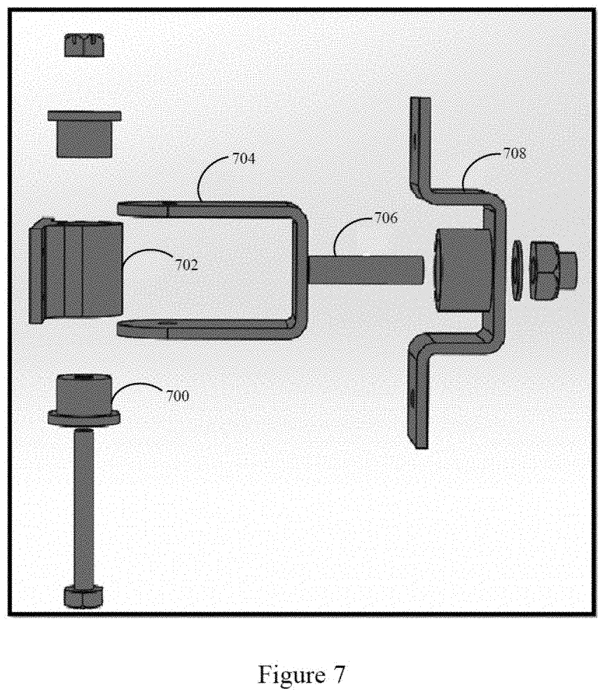

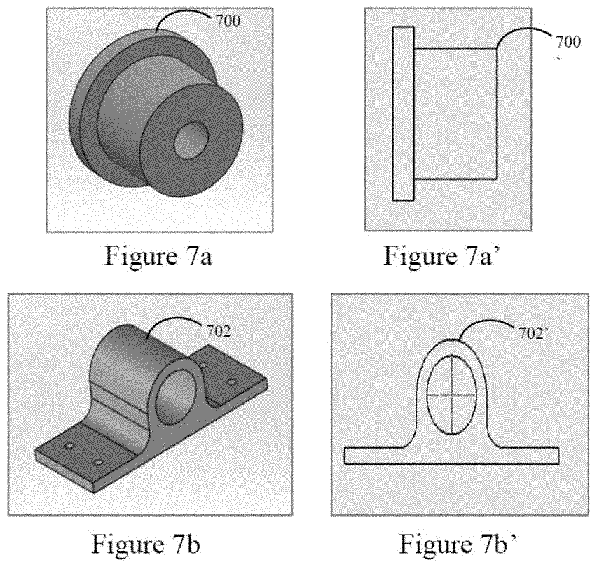

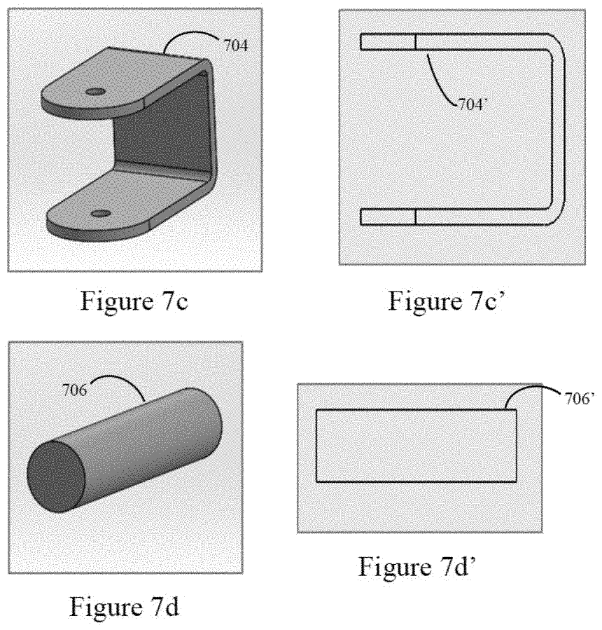

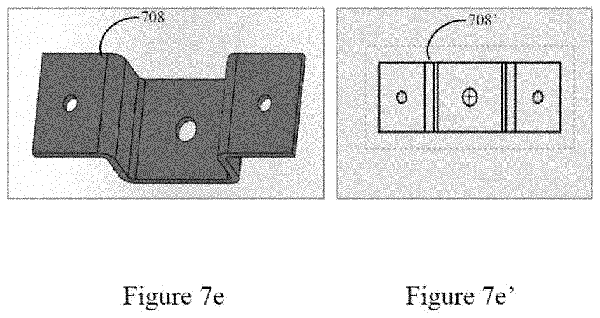

Referring now to an exemplary product as illustrated in FIG. 7, working of the system 102 for classifying elements of a product is explained. The product is made of different elements which are manufactured using different mechanical operations. The elements identified to be present in the product include a Bush 700, a Pivot 702, U-Support 704, a Pin 706, and a Bracket 708.

In accordance with the above defined priority of identifying elements, the system 102 may firstly identify the Bush 700 from its 3D representation, as illustrated in FIG. 7a. From the 3D representation, the system 102 may determine a 2D representation of the Bush 700, as illustrated in FIG. 7a′. The system 102 may determine that the Bush 700 will be manufactured using the turn operation, as the Bush 700 is axis symmetric and has cylindrical faces. An external end profile and an internal end profile of the Bush 700 may also be determined.

Successively, the system 102 may identify the Pivot 702 from its 3D representation, as illustrated in FIG. 7b. From the 3D representation, the system 102 may determine a 2D representation of the Pivot 702, as illustrated in FIG. 7b′. The system 102 may determine that the Pivot 702 will be manufactured using the machining operation, as the Pivot 702 comprises 5-hole features and 2-slot features.

Successively, the system 102 may identify the U-Support 704 from its 3D representation, as illustrated in FIG. 7c. From the 3D representation, the system 102 may determine a 2D representation of the U-Support 704, as illustrated in FIG. 7c′. The system 102 may determine that the U-Support 704 will be manufactured using the sheet metal operation, as the U-Support 704 has a uniform thickness and comprises 3 walls and 2 bend features.

Thereupon, the system 102 may identify the Pin 706 from its 3D representation, as illustrated in FIG. 7d. From the 3D representation, the system 102 may determine a 2D representation of the Pin 706, as illustrated in FIG. 7d′. The system 102 may determine that the Pin 706 will be manufactured using the turn operation, as the Pin 706 is axis symmetric and has cylindrical faces.

Finally, the system 102 may identify the Bracket 708 from its 3D representation, as illustrated in FIG. 7e. From the 3D representation, the system 102 may determine a 2D representation of the Bracket 708, as illustrated in FIG. 7e′. The system 102 may determine that the Bracket 708 will be manufactured using the machining operation, as the Bracket 708 comprises holes, slots, and island features.

In the above described manner, manufacturing process required to produce different elements of a product could be automatically determined and operation of an entire manufacturing assembly could be automated.

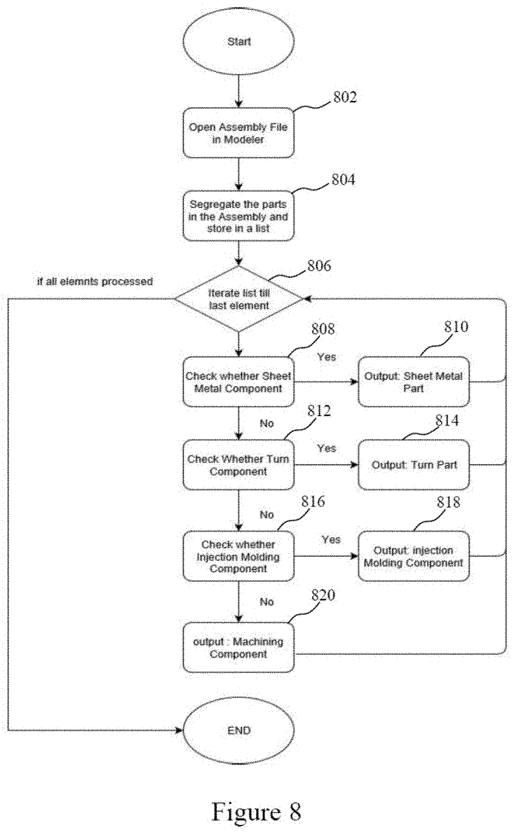

Referring now to FIG. 8, a method 800 for classifying elements of a product is described, in accordance with an embodiment of the present subject matter. The method 800 may be described in the general context of computer executable instructions. Generally, computer executable instructions can include routines, programs, objects, components, data structures, procedures, modules, functions, etc., that perform particular functions or implement particular abstract data types.

The order in which the method 800 for classifying elements of a product is described is not intended to be construed as a limitation, and any number of the described method blocks can be combined in any order to implement the method 800 or alternate methods. Additionally, individual blocks may be deleted from the method 800 without departing from the spirit and scope of the subject matter described herein. Furthermore, the method can be implemented in any suitable hardware, software, firmware, or combination thereof. However, for ease of explanation, in the embodiments described below, the method 800 may be considered to be implemented in the above described system 102.

At block 802, an assembly file including details of a product is opened in a 3D modeler tool.

At block 804, all the parts/elements present in the product are identified and segregated, and their details stored as different elements in a list.

At block 806, starting from beginning, all the elements present in the list are traversed.

At block 808, presence of sheet metal elements in the list is identified. In case, sheet metal elements are identified, their details are forwarded to a sheet metal operation machine, at block 810.

At block 812, presence of turn elements in the list is identified. In case, turn elements are identified, their details are forwarded to a turn operation machine, at block 814.

At block 816, presence of injection moulding elements in the list is identified. In case, injection moulding elements are identified, their details are forwarded to an injection moulding operation machine, at block 818.

At block 820, details of remaining elements are forwarded for machining operation.

Thereupon, at block 806, it is determined if details of all the elements present in the list is traversed. If details of all the elements are found to be traverse, the program ends.

Although implementations for methods and systems for classifying elements of a product have been described in language specific to structural features and/or methods, it is to be understood that the appended claims are not necessarily limited to the specific features or methods described. Rather, the specific features and methods are disclosed as examples of implementations for classifying elements of a product.

1. A method for classifying elements of a product, the method comprising:
identifying one or more elements of the product; and
determining, using a feature recognition technique, features of the one or more elements, wherein the features correspond to manufacturing operations required for manufacturing of the one or more elements, and wherein the manufacturing operations include at least one of sheet metal operations, turn operations, injection moulding operations, and machining operations, and wherein the manufacturing operations are determined in a priority order with the sheet metal operation having a highest priority and the machining operation having a least priority.

2. The method as claimed in claim 1, wherein the one or more elements of the product are identified from a three-dimensional representation of the product.

3. The method as claimed in claim 1, wherein the sheet metal operations include walls, bends, cut-outs, flanges, and stamps.

4. The method as claimed in claim 1, wherein the turn operations include an external end profile feature and an internal end profile feature.

5. The method as claimed in claim 1, wherein the injection moulding operations include ribs and boss.

6. The method as claimed in claim 1, wherein the machining operations include holes, pockets, slots, and islands.

7. The method as claimed in claim 6, wherein the holes are one of counter-bore holes, counter-sunk holes, counter-drill holes, taper holes, and simple holes, the pockets are blind pockets or through pockets, and the slots are blind slots or through slots.

8. The method as claimed in claim 1, wherein the feature recognition technique operates on boundary representation models.

9. The method as claimed in claim 1, wherein details of the features are stored for later execution by different units of a manufacturing plant for manufacturing the product.

10. A system for classifying elements of a product, the system comprising:
a processor; and
a memory coupled to the processor, wherein the memory stores programmed instructions executable by the processor for:
identifying one or more elements of the product; and
determining, using a feature recognition technique, features of the one or more elements, wherein the features correspond to manufacturing operations required for manufacturing the one or more elements, and wherein the manufacturing operations include at least one of sheet metal operations, turn operations, injection moulding operations, and machining operations, and wherein the manufacturing operations are determined in a priority order with the sheet metal operation having a highest priority and the machining operation having a least priority.
